(19) United States
(12) Patent Application Publication
(10) Pub. No.: US 2023/0354709 A1
(43) Pub. Date: Nov. 2, 2023

(54) Method Of Manufacturing Piezoelectric Element

(71) Applicant: SEIKO EPSON CORPORATION, Tokyo (JP)

(72) Inventors: Motoki TAKABE, Shiojiri (JP); Eiju HIRAI, Azumino (JP)

(21) Appl. No.: 18/308,111

(22) Filed: Apr. 27, 2023

(30) Foreign Application Priority Data
Apr. 28, 2022 (JP) 2022-074923

(51) Int. Cl. H10N 30/063; H10N 30/082; H10N 30/50; H10N 30/00; H10N 30/05; B41J 2/14

(52) U.S. Cl. CPC H10N 30/063; H10N 30/082; H10N 30/501; H10N 30/1051; H10N 30/05; B41J 2/14233; B41J 2002/14258

(57) ABSTRACT

A method of manufacturing a piezoelectric element of the present disclosure includes: a first film forming step of forming a first electrode at a substrate; a second film forming step of forming a first piezoelectric layer at the first electrode; a first processing step of patterning the first electrode and the first piezoelectric layer by etching; and a third film forming step of forming, after the first processing step, a second piezoelectric layer to cover the first electrode, the first piezoelectric layer, and the substrate.

The present application is based on, and claims priority from JP Application Serial Number 2022-074923, filed Apr. 28, 2022, the disclosure of which is hereby incorporated by reference herein in its entirety.

### BACKGROUND

### 1. Technical Field

The present disclosure relates to a method of manufacturing a piezoelectric element.

### 2. Related Art

A piezoelectric element generally includes a substrate, a piezoelectric layer having an electromechanical conversion characteristic, and two electrodes sandwiching the piezoelectric layer. In recent years, development of devices (piezoelectric element application devices) using such a piezoelectric element as a driving source has been actively performed. One of the piezoelectric element application devices is a liquid ejection head represented by an ink jet recording head, a MEMS element represented by a piezoelectric MEMS element, an ultrasonic measurement device represented by an ultrasonic sensor, and further, a piezoelectric actuator device.

Lead zirconate titanate (PZT) is known as a material (piezoelectric material) for the piezoelectric layer of the piezoelectric element. In recent years, non-lead-based piezoelectric materials having a reduced lead content have been developed from the viewpoint of environmental loading reduction.

Further, in recent years, there has been a strong demand for further size reduction and higher performance of various electronic devices, electronic components, and the like, and accordingly, size reduction and higher performance of piezoelectric elements have also been demanded.

JP-A-2018-160535 discloses a piezoelectric element in which a piezoelectric layer containing potassium, sodium, and niobium is formed at a surface of a patterned lower electrode.

As described above, the piezoelectric elements using the non-lead-based piezoelectric material such as piezoelectric elements (KNN-based piezoelectric elements) using potassium sodium niobate (KNN; (K,Na)NbO₃) have been proposed. However, as in JP-A-2018-160535, when the piezoelectric layer is formed at the lower electrode patterned by etching processing, crystal orientation of the piezoelectric layer may be deteriorated, and problems such as generation of cracks and voids may occur.

In view of such circumstances, a piezoelectric layer having excellent crystal orientation is demanded in a non-lead-based piezoelectric element.

Such a problem is not limited to a piezoelectric element used in a piezoelectric actuator mounted on a liquid ejection head represented by an ink jet recording head, and similarly exists in a piezoelectric element used in another piezoelectric element application device.

### SUMMARY

In order to solve the above problems, according to a first aspect of the present disclosure, there is provided a method of manufacturing a piezoelectric element, and the method includes: a first film forming step of forming a first electrode at a substrate; a second film forming step of forming a first piezoelectric layer at the first electrode; a first processing step of patterning the first electrode and the first piezoelectric layer by etching; and a third film forming step of forming, after the first processing step, a second piezoelectric layer to cover the first electrode, the first piezoelectric layer, and the substrate.

### BRIEF DESCRIPTION OF THE DRAWINGS

FIG. 1 is a cross-sectional view schematically showing a piezoelectric element according to a first embodiment.

FIG. 2 is a flowchart showing a method of manufacturing the piezoelectric element according to the first embodiment.

FIG. 3A is a cross-sectional view schematically showing a manufacturing process of the piezoelectric element according to the first embodiment.

FIG. 3B is a cross-sectional view schematically showing the manufacturing process of the piezoelectric element according to the first embodiment.

FIG. 3C is a cross-sectional view schematically showing the manufacturing process of the piezoelectric element according to the first embodiment.

FIG. 3D is a cross-sectional view schematically showing the manufacturing process of the piezoelectric element according to the first embodiment.

FIG. 3E is a cross-sectional view schematically showing the manufacturing process of the piezoelectric element according to the first embodiment.

FIG. 4 is a cross-sectional view schematically showing a piezoelectric element according to a modification of the first embodiment.

FIG. 5 is a flowchart showing a method of manufacturing the piezoelectric element according to the modification of the first embodiment.

FIG. 6A is a cross-sectional view schematically showing a manufacturing process of the piezoelectric element according to the modification of the first embodiment.

FIG. 6B is a cross-sectional view schematically showing the manufacturing process of the piezoelectric element according to the modification of the first embodiment.

FIG. 7 is a cross-sectional view schematically showing a piezoelectric element according to a second embodiment.

FIG. 8 is a flowchart showing a method of manufacturing the piezoelectric element according to the second embodiment.

FIG. 9A is a cross-sectional view schematically showing a manufacturing process of the piezoelectric element according to the second embodiment.

FIG. 9B is a cross-sectional view schematically showing the manufacturing process of the piezoelectric element according to the second embodiment.

FIG. 9C is a cross-sectional view schematically showing the manufacturing process of the piezoelectric element according to the second embodiment.

FIG. 9D is a cross-sectional view schematically showing the manufacturing process of the piezoelectric element according to the second embodiment.

FIG. 9E is a cross-sectional view schematically showing the manufacturing process of the piezoelectric element according to the second embodiment.

FIG. 10 is an exploded perspective view schematically showing a liquid ejection head according to the embodiment.

FIG. 11 is a plan view schematically showing the liquid ejection head according to the embodiment.

FIG. 12 is a cross-sectional view schematically showing the liquid ejection head according to the embodiment.

FIG. 13 is a perspective view schematically showing a printer according to the embodiment.

### DESCRIPTION OF EXEMPLARY EMBODIMENTS

Hereinafter, embodiments of the present disclosure will be described with reference to the drawings. The following description shows an aspect of the present disclosure, and can be freely changed without departing from the gist of the present disclosure. In the drawings, the same reference signs denote the same members, and the description thereof is omitted as appropriate. The number after a letter which makes up the reference sign is referenced by a reference sign which includes the same letter and is used to distinguish between elements which have similar configurations. When it is not necessary to distinguish elements indicated by the reference signs which include the same letter from each other, each of the elements is referenced by a reference sign containing only a letter.

In each drawing, X, Y, and Z represent three spatial axes orthogonal to one another. In the present description, directions along these axes are referred to as a first direction X (X-direction), a second direction Y (Y-direction), and a third direction Z (Z-direction), respectively, a direction of an arrow in each drawing is referred to as a positive (+) direction, and a direction opposite from the arrow is referred to as a negative (−) direction. The X-direction and the Y-direction represent in-plane directions of a plate, a layer, and a film, and the Z-direction represents a thickness direction or a stacking direction of a plate, a layer, and a film.

Components shown in each drawing, that is, a shape and size of each part, a thickness of a plate, a layer, and a film, a relative positional relation, a repeating unit, and the like may be exaggerated for describing the present disclosure. Furthermore, the term “above” in the present description does not limit that a positional relation between the components is “directly above”. For example, expressions such as “a first electrode on a substrate” and “a piezoelectric layer on the first electrode”, which will be described later, do not exclude those including other components between the substrate and the first electrode or between the first electrode and the piezoelectric layer.

### First Embodiment

First, a piezoelectric element and a method of manufacturing the piezoelectric element according to a first embodiment will be described with reference to the drawings.

### Piezoelectric Element

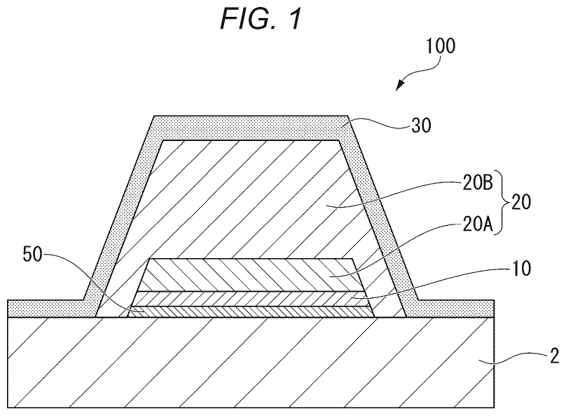

FIG. 1 is a cross-sectional view schematically showing a piezoelectric element 100 according to the embodiment.

As shown in FIG. 1, the piezoelectric element 100 includes a first electrode (lower electrode) 10, a piezoelectric layer 20, and a second electrode 30. The piezoelectric layer 20 includes a first piezoelectric layer 20A and a second piezoelectric layer 20B in this order from the first electrode 10 side. The piezoelectric element 100 is provided at the substrate 2.

The substrate 2 is, for example, a flat plate formed of a semiconductor, an insulator, and the like. The substrate 2 may be a single-layer structure or a stack body in which a plurality of layers are stacked. An internal structure of the substrate 2 is not limited as long as an upper surface thereof has a planar shape, and the substrate 2 may have a structure in which a space and the like is formed therein.

The substrate 2 may include a vibrating plate that has flexibility and is deformed by the operation of the piezoelectric layer 20. The vibrating plate is, for example, a silicon oxide layer, a zirconium oxide layer, or a stack body in which the zirconium oxide layer is provided at the silicon oxide layer.

The first electrode 10 is provided at the substrate 2. The first electrode 10 is provided between the substrate 2 and the first piezoelectric layer 20A. A shape of the first electrode 10 is, for example, a layered shape. A thickness of the first electrode 10 is, for example, 5 nm or more and 500 nm or less. The first electrode 10 is, for example, a metal layer such as a platinum layer, an iridium layer, or a ruthenium layer, a conductive oxide layer thereof, a lanthanum nickelate (LaNiO₃:LNO) layer, or a strontium ruthenate (SrRuO₃:SRO) layer. The first electrode 10 may have a structure in which the plurality of layers exemplified above are stacked.

An adhesion layer 50 such as a titanium layer may be provided between the substrate 2 and the first electrode 10. The adhesion layer 50 is made of, for example, titanium oxide (TiO_{X}), titanium (Ti), SiN, and the like, and has a function of improving adhesion between the piezoelectric layer 20 and the substrate 2. When a titanium oxide (TiO_{X}) layer, a titanium (Ti) layer, or a silicon nitride (SiN) layer is used as the adhesion layer, the adhesion layer 50 also has a function as a stopper that prevents constituent elements (for example, potassium and sodium) of the piezoelectric layer 20 from passing through the first electrode 10 and reaching the substrate 2 when the piezoelectric layer 20 to be described later is formed. The adhesion layer 50 may be omitted.

The first electrode 10 is one electrode for applying a voltage to the piezoelectric layer 20. The first electrode 10 is a lower electrode provided below the piezoelectric layer 20.

The piezoelectric layer 20 is provided at the first electrode 10. The piezoelectric layer 20 includes the first piezoelectric layer 20A and the second piezoelectric layer 20B. In the example shown in FIG. 1, the first piezoelectric layer 20A is provided at the first electrode 10. The second piezoelectric layer 20B covers the first piezoelectric layer 20A and the substrate 2. Although not shown, the second piezoelectric layer 20B may not be provided at the substrate 2, and may be provided only at the first piezoelectric layer 20A. A thickness of the first piezoelectric layer 20A is, for example, 5 nm or more and 500 nm or less. A thickness of the second piezoelectric layer 20B is, for example, 100 nm or more and 3 μm or less. The piezoelectric layer 20 including the first piezoelectric layer 20A and the second piezoelectric layer 20B can be deformed by applying a voltage between the first electrode 10 and the second electrode 30.

The first piezoelectric layer 20A and the second piezoelectric layer 20B are preferably a composite oxide having a perovskite structure represented by a general formula ABO₃, and more preferably include a piezoelectric material composed of potassium sodium niobate (KNN-based composite oxide; (K,Na)NbO₃) represented by the following formula (1).

(K_{X},Na_{1-X})NbO₃

(0.1≤X≤0.9) (1)

The composite oxide represented by the above formula (1) is a so-called KNN-based composite oxide. Since the KNN-based composite oxide is a non-lead-based piezoelectric material in which a content of lead (Pb) and the like is reduced, the KNN-based composite oxide is excellent in biocompatibility and has low environmental loading. In addition, since the KNN-based composite oxide is excellent in piezoelectric characteristics among non-lead-based piezoelectric materials, it is advantageous for improving various characteristics.

The first piezoelectric layer 20A and the second piezoelectric layer 20B may contain additives other than the elements (for example, niobium, potassium, calcium, and oxygen) constituting the composite oxide having the perovskite structure described above. That is, the first piezoelectric layer 20A may be, for example, a KNN layer to which an additive is added. Examples of such an additive include manganese (Mn). A material of the first electrode 10 and a material of the second electrode 30 may be the same or different.

The first piezoelectric layer 20A does not include, for example, a lead oxide (PbO) layer. Whether the first piezoelectric layer 20A does not include a lead oxide layer can be confirmed by, for example, X-ray diffraction (XRD) measurement.

The second electrode 30 is provided at the second piezoelectric layer 20B. The second electrode 30 may be further provided at a side surface of the second piezoelectric layer 20B and at the substrate 2 as long as the second electrode 30 is electrically separated from the first electrode 10.

A shape of the second electrode 30 is, for example, a layered shape. A thickness of the second electrode 30 is, for example, 10 nm or more and 1000 nm or less. The second electrode 30 is, for example, a metal layer such as an iridium layer, a platinum layer, or a ruthenium layer, a conductive oxide layer thereof, a lanthanum nickelate layer, or a strontium ruthenate layer. The second electrode 30 may have a structure in which the plurality of layers exemplified above are stacked. The material of the first electrode 10 and the material of the second electrode 30 may be the same or different.

The second electrode 30 is the other electrode for applying a voltage to the piezoelectric layer 20. The second electrode 30 functions as an upper electrode provided at the piezoelectric layer 20.

### Method of Manufacturing Piezoelectric Element

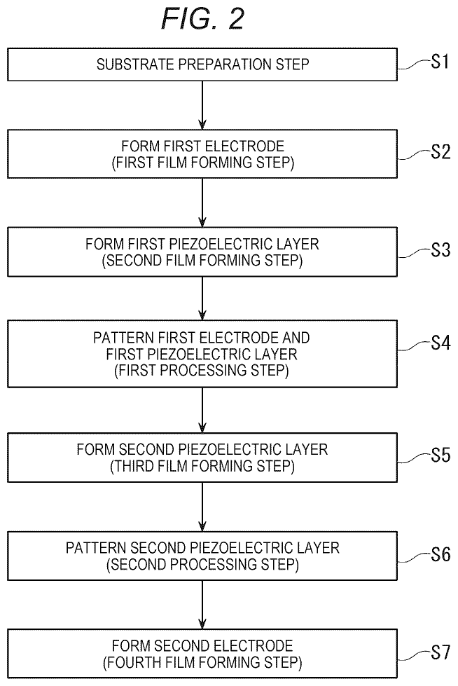

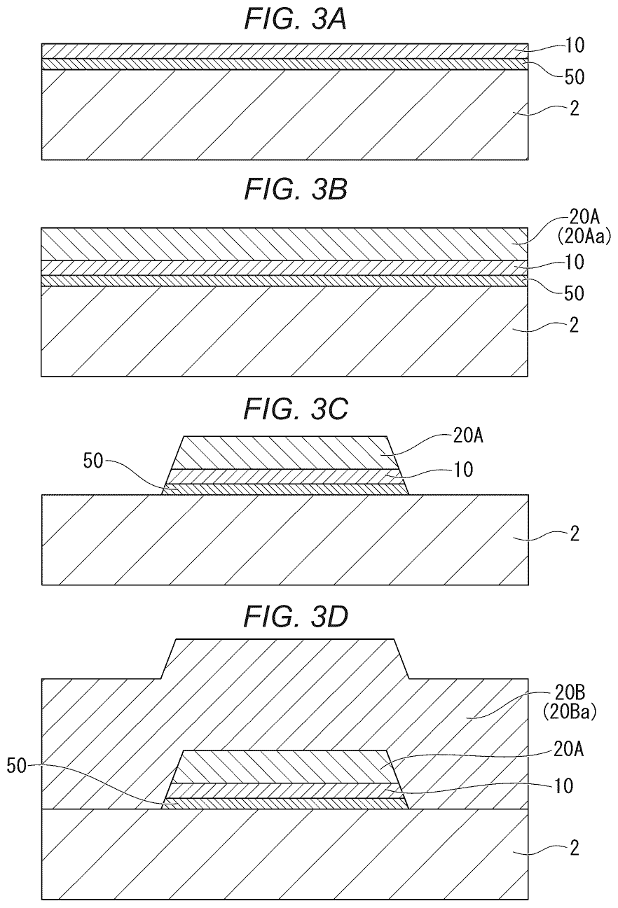

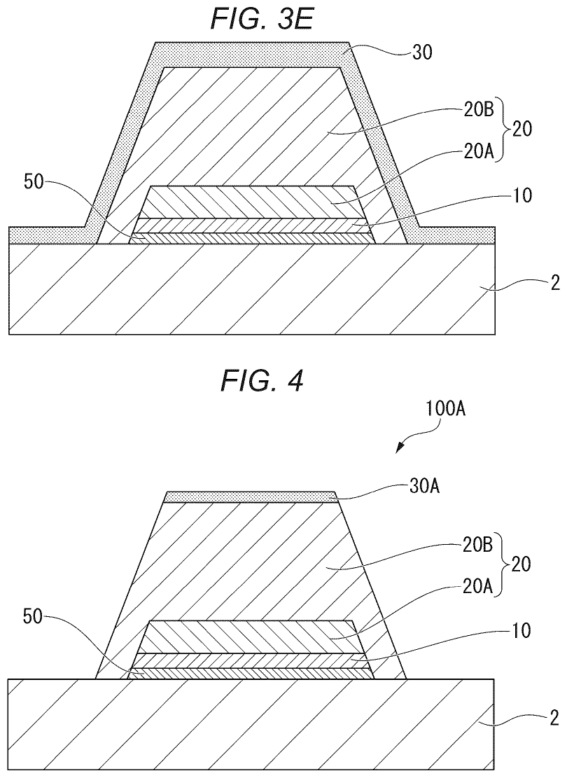

Next, a method of manufacturing the piezoelectric element 100 according to the embodiment will be described with reference to the drawings. FIG. 2 is a flowchart showing the method of manufacturing the piezoelectric element 100 according to the embodiment. FIGS. 3A to 3E are cross-sectional views schematically showing a manufacturing process of the piezoelectric element 100 according to the embodiment. Hereinafter, a case where the first piezoelectric layer 20A and the second piezoelectric layer 20B are manufactured by a chemical solution method (wet method) will be described. The manufacturing method of the first piezoelectric layer 20A and the second piezoelectric layer 20B is not limited to the wet method, and may be, for example, a gas phase method.

As shown in FIG. 3A, the substrate 2 is prepared (substrate preparation step; step S1).

Specifically, for example, a silicon oxide layer is formed by thermally oxidizing a silicon substrate. Next, a zirconium layer is formed at the silicon oxide layer by a sputtering method and the like, and the zirconium layer is thermally oxidized to form a zirconium oxide layer. Through the above steps, the substrate 2 can be prepared.

Next, the first electrode 10 is formed at the substrate 2 (first film forming step; step S2).

The first electrode 10 is formed by, for example, a sputtering method or a vacuum deposition method. When the adhesion layer 50 is provided, a metal titanium film and the like is formed as the adhesion layer 50 at the substrate 2, and then the first electrode 10 is formed. The adhesion layer 50 can be formed by a sputtering method and the like.

Next, as shown in FIG. 3B, the first piezoelectric layer 20A is formed (second film forming step; step S3).

The first piezoelectric layer 20A is obtained by, for example, forming a plurality of piezoelectric films. The first piezoelectric layer 20A is formed by the plurality of piezoelectric films. The first piezoelectric layer 20A can be formed by, for example, a chemical solution method (wet method) of obtaining a metal oxide by applying and drying a solution containing a metal complex (precursor solution), and then performing firing at a high temperature. In addition, the first piezoelectric layer 20A can be formed by a laser ablation method, a sputtering method, a pulse laser deposition method (PLD method), a chemical vapor deposition (CVD) method, an aerosol deposition method, and the like. In the embodiment, from the viewpoint of improving the crystal orientation of the first piezoelectric layer 20A, it is preferable to use a wet method (liquid phase method).

Here, the wet method is a method of deposition by a chemical solution method such as a MOD method or a sol-gel method, and is a concept distinguished from a gas phase method such as a sputtering method. In the embodiment, a gas phase method may be used in addition to the wet method.

For example, the first piezoelectric layer 20A formed by the wet method (liquid phase method) includes a plurality of piezoelectric films 20Aa formed by a series of steps including a step (applying step) of applying a precursor solution and forming a precursor film, a step (drying step) of drying the precursor film, a step (degreasing step) of heating and degreasing the dried precursor film, and a step (firing step) of firing the degreased precursor film. That is, the first piezoelectric layer 20A is formed by repeating the series of steps from the applying step to the firing step a plurality of times. In the series of steps described above, the firing step may be performed after repeating the steps from the applying step to the degreasing step a plurality of times.

A specific procedure for forming the first piezoelectric layer 20A by the wet method (liquid phase method) is, for example, as follows.

First, a precursor solution containing a predetermined metal complex is prepared. The precursor solution is obtained by, in an organic solvent, dissolving or dispersing a metal complex capable of forming a composite oxide containing K, Na, and Nb by firing. At this time, a metal complex containing an additive such as Mn, Li, or Cu may be further mixed. By mixing the metal complex containing Mn, Li, or Cu with the precursor solution, it is possible to further increase the insulation of the obtained first piezoelectric layer 20A.

Examples of a metal complex containing potassium (K) include potassium 2-ethylhexanoate and potassium acetate. Examples of a metal complex containing sodium (Na) include sodium 2-ethylhexanoate and sodium acetate. Examples of a metal complex containing niobium (Nb) include niobium 2-ethylhexanoate and pentaethoxyniobium. When Mn is added as the additive, examples of a metal complex containing Mn include manganese 2-ethylhexanoate. When Li is added as the additive, examples of a metal complex containing Li include lithium 2-ethylhexanoate. At this time, two or more kinds of metal complexes may be used in combination. For example, potassium 2-ethylhexanoate and potassium acetate may be used in combination as the metal complex containing potassium (K). Examples of a solvent include 2-n-butoxyethanol, n-octane, and mixed solvents thereof. The precursor solution may contain an additive which stabilizes dispersion of the metal complex containing K, Na, and Nb. Examples of such an additive include 2-ethylhexanoic acid.

As shown in FIG. 3B, the precursor solution is applied onto the first electrode 10 to form a precursor film (applying step).

Next, the precursor film is heated at a predetermined temperature, for example, about 200° C. to 450° C. and is dried for a certain period of time (drying step).

Next, the dried precursor film is heated to a predetermined temperature, for example, 350° C. to 450° C., and is held at this temperature for a certain period of time to perform degreasing (degreasing step).

Finally, the degreased precursor film is heated to a high temperature, for example, about 600° C. to 850° C., and held at this temperature for a certain period of time to be crystallized. Accordingly, the piezoelectric film is completed (firing step).

The heating temperature in the firing step is preferably high from the viewpoint of increasing a density of the first piezoelectric layer 20A and improving the crystal orientation. Specifically, the heating temperature is preferably 700° C. or higher. More preferably, the heating temperature is 750° C. or higher, but when the heating temperature in the firing step is excessively high, an alkali metal diffuses into the first electrode, so that the composition may change and the crystal orientation may decrease. Therefore, the heating temperature is preferably 850° C. or lower.

Examples of a heating device used in the drying step, the degreasing step, and the firing step include a rapid thermal annealing (RTA) device which performs heating by irradiation with an infrared lamp, and a hot plate. By repeating the above steps a plurality of times, the first piezoelectric layer 20A including the plurality of piezoelectric films 20Aa is formed.

The number of repetitions of the series of steps is not particularly limited. The first piezoelectric layer 20A including one piezoelectric film 20Aa may be formed without repeating the above steps a plurality of times.

In the series of steps from the applying step to the firing step, the firing step may be performed after repeating the steps from the applying step to the degreasing step a plurality of times.

By the above steps, as shown in FIG. 3B, the first piezoelectric layer 20A can be formed at the first electrode 10.

Next, as shown in FIG. 3C, the first electrode 10 and the first piezoelectric layer 20A are patterned (first processing step; step S4).

The patterning in the first processing step is performed by, for example, photolithography and etching. By the first processing step, an upper surface of the substrate 2, a side surface of the first electrode 10, and a side surface of the first piezoelectric layer 20A are exposed.

Next, as shown in FIG. 3D, the second piezoelectric layer 20B is formed at the substrate 2 and the first piezoelectric layer 20A (third film forming step; step S5).

Similarly to the first piezoelectric layer 20A, the second piezoelectric layer 20B is obtained by, for example, forming a plurality of piezoelectric films 20Ba. The second piezoelectric layer 20B is formed by the plurality of piezoelectric films 20Ba. Similarly to the first piezoelectric layer 20A, the second piezoelectric layer 20B can be formed by a wet method. In addition, the second piezoelectric layer 20B can be formed by a laser ablation method, a sputtering method, a pulse laser deposition method (PLD method), a chemical vapor deposition (CVD) method, an aerosol deposition method, and the like. In the embodiment, from the viewpoint of improving the crystal orientation of the second piezoelectric layer 20B, it is preferable to use a wet method (liquid phase method). A film forming method of the first piezoelectric layer 20A and a film forming method of the second piezoelectric layer 20B may be the same or different.

Here, in the manufacturing method of the embodiment, before and after the second piezoelectric layer 20B is formed at the first piezoelectric layer 20A and before and after the second electrode 30 is formed at the second piezoelectric layer 20B, a reheating treatment (post-annealing) may be performed in a temperature range of 600° C. to 800° C. as necessary. By performing the post-annealing thus, a good interface between the first piezoelectric layer 20A and the first electrode 10 and a good interface between the second piezoelectric layer 20B and the second electrode 30 can be formed. By performing the post-annealing, the crystallinity of the piezoelectric layer 20 can be improved, and the insulation of the piezoelectric layer 20 can be further improved.

Next, as shown in FIG. 3E, the second piezoelectric layer 20B is patterned (second processing step; step S6), and then the second electrode 30 is formed at the second piezoelectric layer 20B (fourth film forming step; step S7).

Specifically, the second piezoelectric layer 20B is patterned into a shape as shown in FIG. 3E. Patterning can be performed by dry etching such as reactive ion etching or ion milling, or wet etching using an etchant.

Thereafter, the second electrode 30 is formed at the second piezoelectric layer 20B. The second electrode 30 is formed by, for example, a sputtering method or a vacuum deposition method.

Through the above steps, the piezoelectric element 100 according to the first embodiment can be manufactured.

The method of manufacturing the piezoelectric element 100 according to the first embodiment has, for example, the following features.

The method of manufacturing the piezoelectric element 100 includes the first film forming step (step S2) of forming the first electrode 10 at the substrate 2, the second film forming step (step S3) of forming the first piezoelectric layer 20A at the first electrode 10, the first processing step (step S4) of patterning the first electrode 10 and the first piezoelectric layer 20A by etching, and the third film forming step (step S5) of forming, after the first processing step, the second piezoelectric layer 20B to cover the first electrode 10, the first piezoelectric layer 20A, and the substrate 2. That is, in the manufacturing method according to the first embodiment, the first piezoelectric layer 20A is formed in advance before the first electrode 10 is patterned by etching processing, and then the first electrode 10 and the first piezoelectric layer 20A are patterned.

In the related art, when a piezoelectric layer is formed at a first electrode patterned by etching processing, crystal orientation of the piezoelectric layer may be deteriorated, and problems such as generation of cracks and voids may occur. It is considered that such a problem is caused by a change in the surface state of an electrode before and after the etching processing, such as deterioration of cleanliness of a surface of the first electrode or attachment of impurities to the surface of the first electrode due to the etching processing. Although a cleaning step may be performed after the etching processing, it is difficult to return a change in the surface of the electrode caused by the etching processing to a state during film forming of the electrode (that is, a surface state with high cleanliness). Specifically, examples of the change in the surface state of the electrode include attachment of elements contained in an etchant, elements of a protective film that cannot be removed in the cleaning step, and impurities such as moisture and carbon in the atmosphere attached by performing the manufacturing process. When the surface state of the first electrode is deteriorated due to these factors, (111) crystal grains are likely to grow when a piezoelectric layer is formed, which causes the generation of cracks and voids.

On the other hand, in the first embodiment, as described above, the first piezoelectric layer 20A is formed in advance before the first electrode 10 is patterned by the etching processing, and then the first electrode 10 and the first piezoelectric layer 20A are patterned by the etching processing. Thereafter, the second piezoelectric layer 20B is formed at the first piezoelectric layer 20A, and the piezoelectric layer 20 including the first piezoelectric layer 20A and the second piezoelectric layer 20B is formed. Through such a manufacturing process, deterioration of the crystal orientation of the first piezoelectric layer 20A can be prevented, and the first piezoelectric layer 20A having good film quality can be obtained. Further, even when some impurities remain on the first piezoelectric layer 20A after the etching processing, the second piezoelectric layer 20B can be grown in accordance with a suitable crystal orientation of the first piezoelectric layer 20A, so that the growth of the (111) crystal grains in the second piezoelectric layer 20B can be prevented. As a result, the generation of cracks, voids, and the like can be prevented over the entire piezoelectric element 100.

When the adhesion layer 50 is provided, since the first electrode 10 covers the adhesion layer 50 during forming of the first piezoelectric layer 20A (see FIG. 3A), even when the piezoelectric film 20Aa is fired in a high temperature range, it is possible to prevent the elements constituting the adhesion layer 50 from diffusing into the first electrode 10.

In the manufacturing method according to the first embodiment, the entire surface of the second piezoelectric layer 20B is covered with the second electrode 30. Accordingly, it is possible to prevent moisture from entering the piezoelectric element 100 from the outside, and as a result, it is possible to prevent defects such as cracks and voids.

### Modification of First Embodiment

Next, a piezoelectric element and a method of manufacturing the piezoelectric element according to a modification of the first embodiment will be described with reference to the drawings.

FIG. 4 is a cross-sectional view schematically showing a piezoelectric element 100A according to the modification of the first embodiment. The piezoelectric element 100A according to the modification is the same as the piezoelectric element 100 according to the first embodiment except for the configuration of the second electrode. Therefore, in the following description, components having the same or similar functions as those in the first embodiment are denoted by the same reference signs. Repeated descriptions of these configurations may be omitted.

As shown in FIG. 4, a second electrode 30A according to the modification may be provided only at the second piezoelectric layer 20B. That is, in the piezoelectric element 100A according to the modification, the second electrode 30A is not provided at the side surface of the second piezoelectric layer 20B, and the side surface of the second piezoelectric layer 20B is exposed.

With such a configuration, the adhesion between the second electrode 30A and the second piezoelectric layer 20B can be improved.

In the modification, a conductive layer may be formed to cover the second electrode 30A and the second piezoelectric layer 20B. A material of the conductive layer may be appropriately determined according to desired characteristics. Examples thereof include a metal layer of platinum, iridium, ruthenium, copper, and the like, a conductive oxide layer thereof, a lanthanum nickelate (LaNiO₃:LNO) layer, and a strontium ruthenate (SrRuO₃:SRO) layer. Accordingly, by providing the conductive layer at the second electrode 30A and the second piezoelectric layer 20B, it is possible to prevent entry of moisture from the outside, and by providing the conductive layer via the second electrode 30A, it is possible to improve the adhesion between the conductive layer and the second piezoelectric layer 20B. The materials of the conductive layer and the second electrode 30 may be the same or different.

In the modification, a protective film may be formed at the side surface of the second piezoelectric layer 20B. Examples of the material of the protective film include a nitride made of TiN, SiN, AlN, TiAlN, and the like, an oxide such as AlOx, TiOx, TaOx, CrOx, IrOx, and HfOx, a resin-based material such as parylene and an adhesive, and a carbon-based material such as a photosensitive resist and diamond-like carbon. Accordingly, by providing the protective film at the side surface of the second piezoelectric layer 20B, it is possible to prevent entry of moisture from the outside. The materials of the conductive layer and the second electrode 30 may be the same or different.

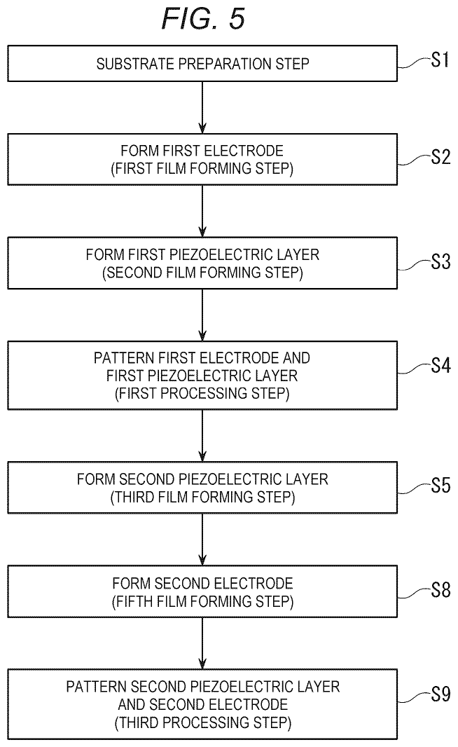

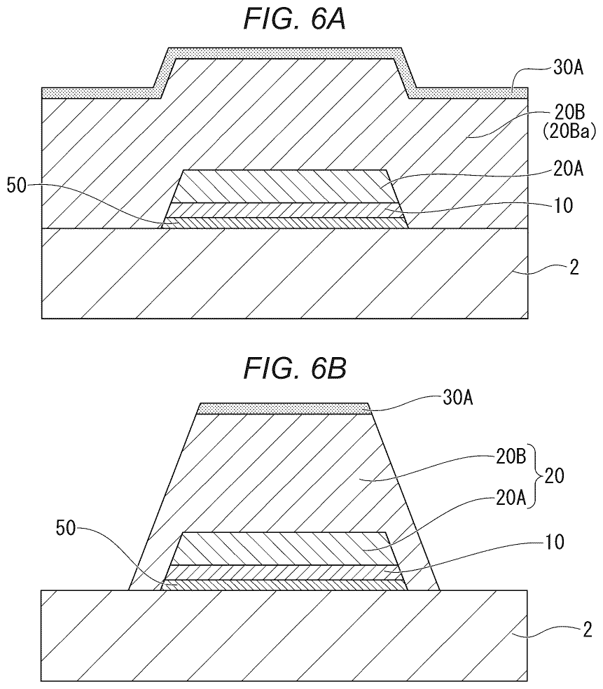

FIG. 5 is a flowchart showing the method of manufacturing the piezoelectric element 100A according to the modification of the embodiment. FIGS. 6A and 6B are cross-sectional views schematically showing a manufacturing process of the piezoelectric element 100A according to the modification. In the modification, similarly to the first embodiment, the method of manufacturing the first piezoelectric layer 20A and the second piezoelectric layer 20B is not limited to the wet method, and may be, for example, a gas phase method. Since the manufacturing method according to the modification is the same as that of the first embodiment up to the third film forming step, the third film forming step and the subsequent steps will be described.

As shown in FIG. 6A, the second electrode 30 is formed at the second piezoelectric layer 20B (fifth film forming step; step S8), and then, as shown in FIG. 6B, the second piezoelectric layer 20B and the second electrode 30 are patterned (third processing step; step S9).

Specifically, as shown in FIG. 6A, the second electrode 30 is formed at the second piezoelectric layer 20B by a sputtering method, a vacuum deposition method, and the like. Thereafter, the second piezoelectric layer 20B and the second electrode 30 are patterned into a shape as shown in FIG. 6B. Patterning can be performed by dry etching such as reactive ion etching or ion milling, or wet etching using an etchant.

When the above-described conductive layer is formed, the conductive layer may be formed to cover the second electrode 30 and the second piezoelectric layer 20B after the third processing step (sixth film forming step).

When the above-described protective film is formed, the protective film may be formed at the side surface of the second piezoelectric layer 20B by a MOD method, a sputtering method, a CVD method, an ALD method, and the like after the third processing step (seventh film forming step). The protective film may be formed by combining two or more of these methods.

### Second Embodiment

Next, a piezoelectric element 100B and a method of manufacturing the piezoelectric element 100B according to a second embodiment will be described with reference to the drawings.

### Piezoelectric Element

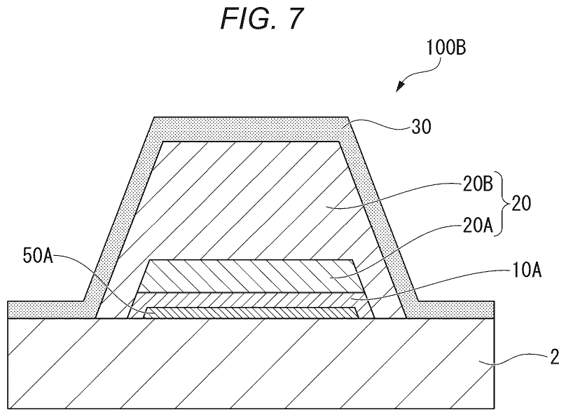

FIG. 7 is a cross-sectional view schematically showing the piezoelectric element 100B according to the second embodiment. The piezoelectric element 100B according to the second embodiment is the same as the piezoelectric element 100 according to the first embodiment except for the configuration of the adhesion layer and the first electrode. Therefore, in the following description, components having the same or similar functions as those in the first embodiment are denoted by the same reference signs. Repeated descriptions of these configurations may be omitted.

As shown in FIG. 7, the first electrode 10A according to the second embodiment covers an upper surface and a side surface of the adhesion layer 50A, and an end portion of the first electrode 10A according to the second embodiment is disposed on the substrate 2. That is, since the first electrode 10A according to the second embodiment covers the adhesion layer 50A, the second piezoelectric layer 20B is provided at the first electrode 10A without being in contact with the adhesion layer 50A.

With such a configuration, elements of the adhesion layer 50A can be prevented from diffusing into the second piezoelectric layer 20B, and the crystallinity of the entire piezoelectric layer 20 can be improved.

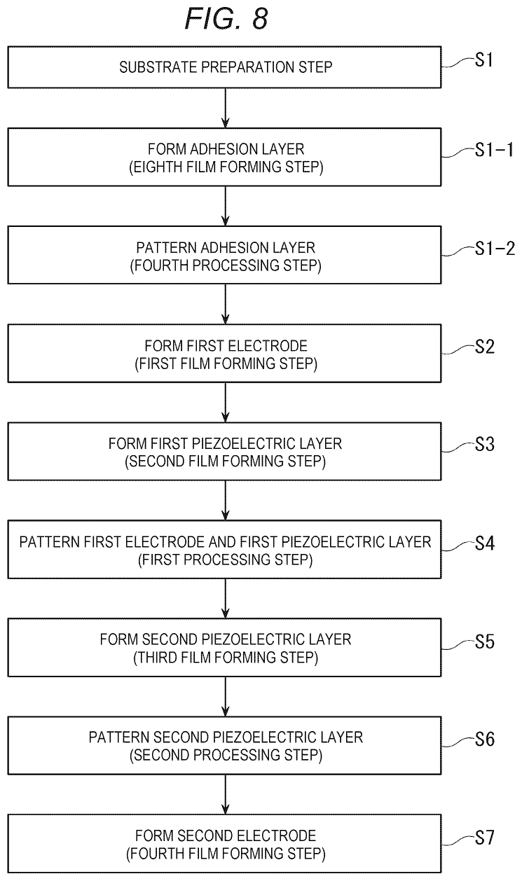

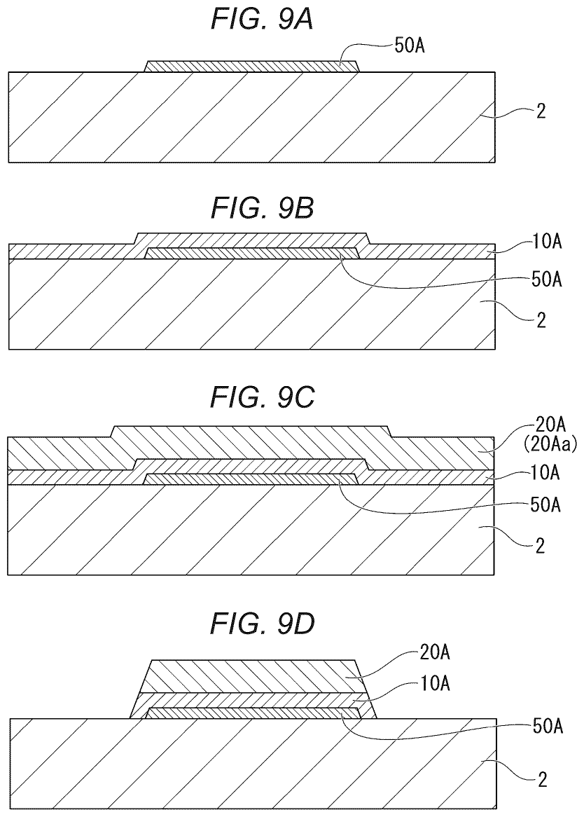

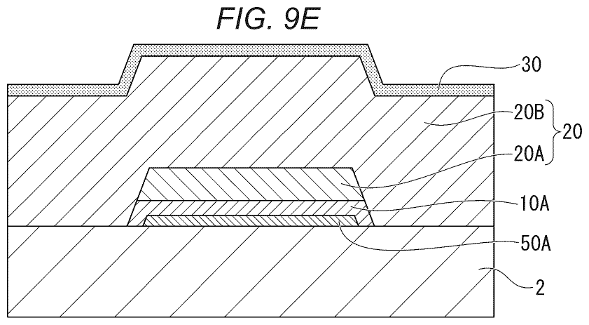

FIG. 8 is a flowchart showing a method of manufacturing the piezoelectric element 100B according to the second embodiment. FIGS. 9A to 9E are cross-sectional views schematically showing a manufacturing process of the piezoelectric element 100B according to the second embodiment. In the second embodiment, similarly to the first embodiment, the method of manufacturing the first piezoelectric layer 20A and the second piezoelectric layer 20B is not limited to the wet method, and may be, for example, a gas phase method.

As shown in the flowchart of FIG. 8, the manufacturing method according to the second embodiment includes, between the substrate preparation step (step S1) and the first film forming step, an eighth film forming step (step S1-1) of forming the adhesion layer 50A and a fourth processing step (step S1-2) of patterning the adhesion layer 50A. Since the other steps are the same as those in the first embodiment, the following description may be omitted.

First, the adhesion layer 50A is formed at the substrate 2 (eighth film forming step; step S1-1). Examples of the material of the adhesion layer 50A include metal titanium, titanium oxide, zinc, zinc oxide, niobium, and copper. The adhesion layer 50A can be formed by a sputtering method and the like.

Next, the adhesion layer 50A is patterned into a shape as shown in FIG. 9A (fourth processing step; step S1-2). The patterning in the first processing step is performed by, for example, photolithography and etching.

Thereafter, as shown in FIGS. 9B and 9C, the first electrode 10A and the first piezoelectric layer 20A are formed (first film forming step and second film forming step). The first film forming step and the second film forming step may be performed in the same manner as in the first embodiment.

Next, the first electrode 10A and the first piezoelectric layer 20A are patterned (first processing step; step S4).

The patterning in the first processing step is performed by, for example, photolithography and etching. At this time, as shown in FIG. 9D, the first electrode 10A and the first piezoelectric layer 20A are patterned, such that the side surface of the adhesion layer 50A is not exposed. By not exposing the side surface of the adhesion layer 50A, the elements of the adhesion layer 50A can be prevented from diffusing into the second piezoelectric layer 20B to be formed later.

Next, as shown in FIG. 9E, the second piezoelectric layer 20B is formed at the substrate 2 and the first piezoelectric layer 20A (third film forming step; step S5).

Thereafter, similarly to the first embodiment, the second electrode 30 may be formed after the second piezoelectric layer 20B is once patterned, or as shown in FIG. 9E, the second electrode 30 may be formed at the second piezoelectric layer 20B (fifth film forming step; step S8), and then the second piezoelectric layer 20B and the second electrode 30 may be patterned (see FIG. 6B).

The method of manufacturing the piezoelectric element 100B according to the second embodiment has, for example, the following features.

The method of manufacturing the piezoelectric element 100B includes, before the first film forming step according to the first embodiment, the eighth film forming step of forming the adhesion layer 50A at the substrate 2 and the fourth processing step of patterning the adhesion layer 50A by etching. That is, in the manufacturing method according to the second embodiment, the adhesion layer 50A is patterned in advance, and then the first electrode 10A covers the upper surface and the side surface of the adhesion layer 50A. The elements of the adhesion layer 50A can be prevented from diffusing into the second piezoelectric layer 20B, and the crystallinity of the entire piezoelectric layer 20 can be improved.

In the piezoelectric element 100B according to the second embodiment, by covering the adhesion layer 50A with the first electrode 10A, the elements of the adhesion layer 50A can be prevented from diffusing into the second piezoelectric layer 20B. Therefore, when the second piezoelectric layer 20B is fired, the second piezoelectric layer 20B can be fired in a higher temperature range.

When the piezoelectric film is fired to form a piezoelectric body, a piezoelectric material can be densified by increasing a firing temperature, and a piezoelectric film having a higher crystallinity can be obtained. However, as the firing temperature is increased, the degree of diffusion of the elements constituting the adhesion layer is also increased in proportion, and thus the film quality of the piezoelectric film is deteriorated. That is, it is difficult to further improve the crystallinity of the piezoelectric layer simply by increasing the firing temperature.

On the other hand, in the second embodiment, since the diffusion of the elements of the adhesion layer 50A into the second piezoelectric layer 20B can be prevented by the first electrode 10A covering the adhesion layer 50A, when the second piezoelectric layer 20B is fired, the firing temperature can be designed without considering the diffusion of the elements of the adhesion layer 50A. For example, in the second embodiment, even when the firing temperature of the second piezoelectric layer 20B is set at the same level as the firing temperature of the first piezoelectric layer 20A, the diffusion of the elements of the adhesion layer 50A can be prevented, and thus the piezoelectric layer 20 having more excellent crystallinity can be obtained.

### Liquid Ejection Head

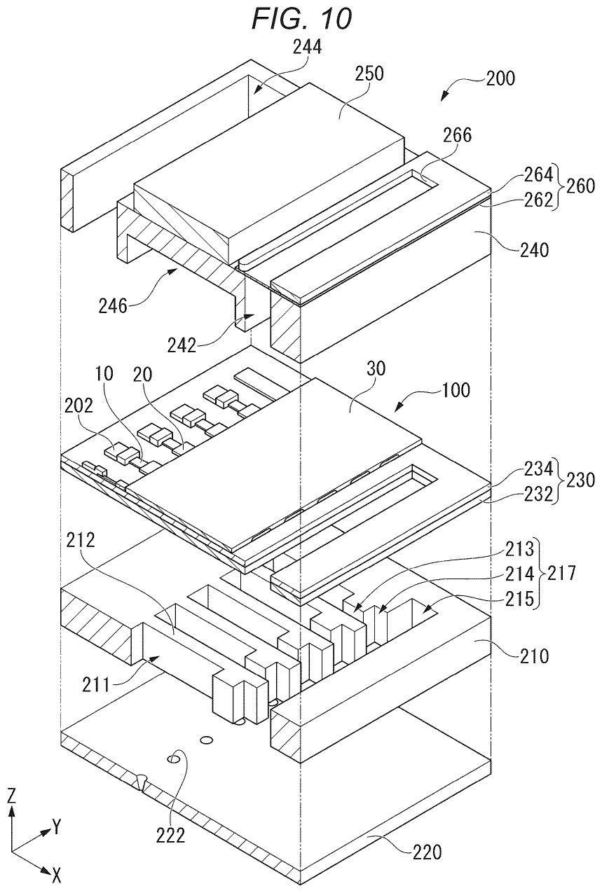

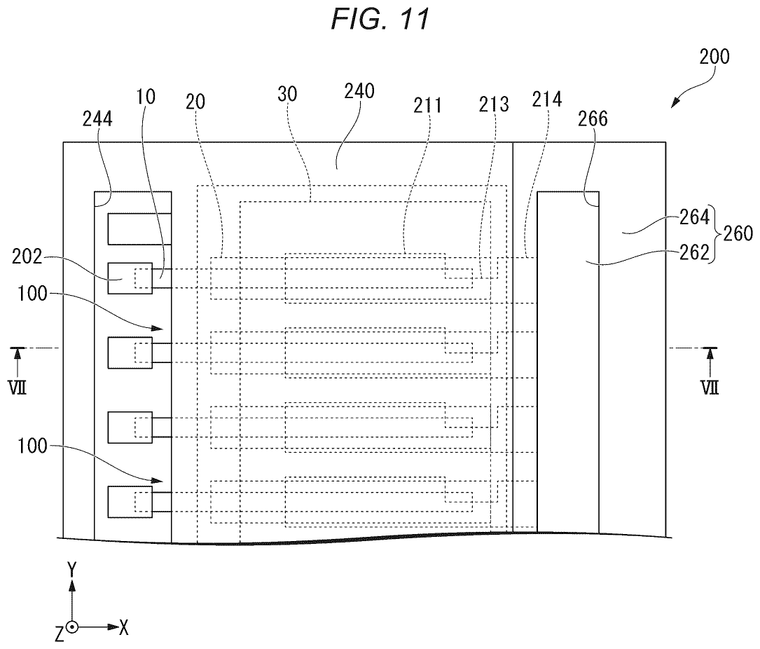

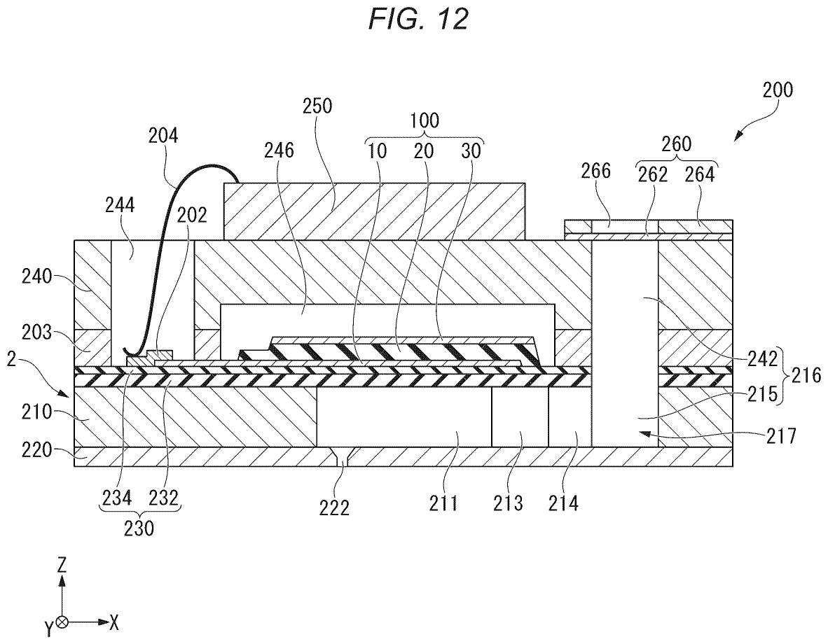

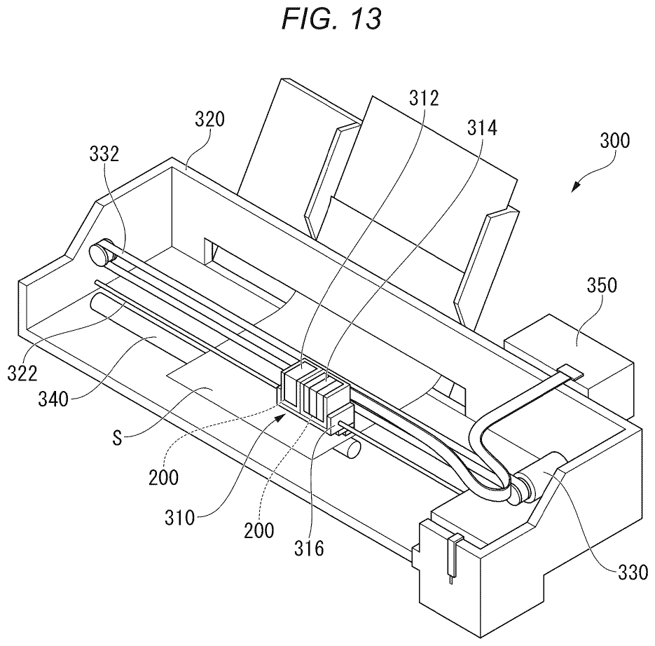

Next, a liquid ejection head according to the embodiment will be described with reference to the drawings. FIG. 10 is an exploded perspective view schematically showing a liquid ejection head 200 according to the embodiment. FIG. 11 is a plan view schematically showing the liquid ejection head 200 according to the embodiment. FIG. 12 is a cross-sectional view taken along a line VII-VII in FIG. 11 schematically showing the liquid ejection head 200 according to the embodiment. In FIGS. 10 to 12, an X-axis, a Y-axis, and a Z-axis are shown as three axes orthogonal to one another. FIGS. 10 to 12 show the piezoelectric element 100 in a simplified manner.

The liquid ejection head 200 includes, for example, the substrate 2, the piezoelectric element 100, a nozzle plate 220, a protective substrate 240, a circuit substrate 250, and a compliance substrate 260, as shown in FIGS. 10 to 12. The substrate 2 includes a flow path formation substrate 210 and a vibrating plate 230. For convenience, illustration of the circuit substrate 250 is omitted in FIG. 11.

The flow path formation substrate 210 is, for example, a silicon substrate. The flow path formation substrate 210 is provided with pressure generation chambers 211. The pressure generation chamber 211 is partitioned by a plurality of partition walls 212. A capacity of the pressure generation chamber 211 is changed by the piezoelectric element 100.

First communication paths 213 and second communication paths 214 are provided at an end of the flow path formation substrate 210 in a +X-axis direction of the pressure generation chambers 211. An opening area of the first communication path 213 is reduced by narrowing an end of the pressure generation chamber 211 in the +X-axis direction from a Y-axis direction. A width of the second communication path 214 in the Y-axis direction is, for example, the same as a width of the pressure generation chamber 211 in the Y-axis direction. A third communication path 215 that communicates with a plurality of second communication paths 214 is provided in the +X-axis direction of the second communication paths 214. The third communication path 215 constitutes a part of a manifold 216. The manifold 216 serves as a common liquid chamber for each of the pressure generation chambers 211. As described above, the flow path formation substrate 210 is provided with the pressure generation chambers 211 and a supply flow path 217 including the first communication paths 213, the second communication paths 214, and the third communication path 215. The supply flow path 217 communicates with the pressure generation chambers 211 and supplies a liquid to the pressure generation chambers 211.

The nozzle plate 220 is provided on one surface of the flow path formation substrate 210. A material of the nozzle plate 220 is, for example, steel use stainless (SUS). The nozzle plate 220 is bonded to the flow path formation substrate 210 by, for example, an adhesive or a thermal welding film. The nozzle plate 220 is provided with a plurality of nozzle holes 222 along the Y axis. The nozzle holes 222 communicate with the pressure generation chambers 211 and eject a liquid.

The vibrating plate 230 is provided on the other surface of the flow path formation substrate 210. The vibrating plate 230 includes, for example, a silicon oxide layer 232 provided at the flow path formation substrate 210 and a zirconium oxide layer 234 provided at the silicon oxide layer 232.

The piezoelectric element 100 is provided, for example, at the vibrating plate 230. The plurality of piezoelectric elements 100 are provided. The number of piezoelectric elements 100 is not particularly limited.

In the liquid ejection head 200, the vibrating plate 230 and the first electrode 10 are displaced by deformation of the piezoelectric layer 20 having electromechanical conversion characteristics. That is, in the liquid ejection head 200, the vibrating plate 230 and the first electrode 10 substantially function as a vibrating plate.

The first electrode 10 is provided as an individual electrode that is independent for each of the pressure generation chambers 211. A width of the first electrode 10 in the Y-axis direction is smaller than the width of the pressure generation chamber 211 in the Y-axis direction. A length of the first electrode 10 in an X-axis direction is larger than a length of the pressure generation chamber 211 in the X-axis direction. Both ends of the first electrode 10 are located in the X-axis direction with both ends of the pressure generation chamber 211 interposed therebetween. A lead electrode 202 is coupled to an end of the first electrode 10 in a −X-axis direction.

A width of the piezoelectric layer 20 in the Y-axis direction is, for example, larger than the width of the first electrode 10 in the Y-axis direction. A length of the piezoelectric layer 20 in the X-axis direction is, for example, larger than the length of the pressure generation chamber 211 in the X-axis direction. An end of the first electrode 10 in the +X-axis direction is located, for example, between an end of the piezoelectric layer 20 in the +X-axis direction and the end of the pressure generation chamber 211 in the +X-axis direction. The end of the first electrode 10 in the +X-axis direction is covered with the piezoelectric layer 20. On the other hand, an end of the piezoelectric layer 20 in the −X-axis direction is located, for example, between the end of the first electrode 10 on the −X-axis direction side and the end of the pressure generation chamber 211 in the +X-axis direction. The end of the first electrode 10 on the −X-axis direction side is not covered with the piezoelectric layer 20.

For example, the second electrode 30 is provided continuously at the piezoelectric layer 20 and the vibrating plate 230. The second electrode 30 is provided as a common electrode common to the plurality of piezoelectric elements 100.

The protective substrate 240 is bonded to the vibrating plate 230 by an adhesive 203 and the like. The protective substrate 240 is provided with a through hole 242. In the shown example, the through hole 242 penetrates the protective substrate 240 in a Z-axis direction and communicates with the third communication path 215. The through hole 242 and the third communication path 215 constitute the manifold 216 that serves as the common liquid chamber for each of the pressure generation chambers 211. Further, the protective substrate 240 is provided with a through hole 244 that penetrates the protective substrate 240 in the Z-axis direction. An end of the lead electrode 202 is located in the through hole 244.

The protective substrate 240 is provided with an opening 246. The opening 246 is a space for not inhibiting driving of the piezoelectric element 100. The opening 246 may or may not be sealed.

The circuit substrate 250 is provided at the protective substrate 240. The circuit substrate 250 includes a semiconductor integrated circuit (IC) for driving the piezoelectric element 100. The circuit substrate 250 and the lead electrode 202 are electrically coupled to each other via a coupling wiring 204.

The compliance substrate 260 is provided at the protective substrate 240. The compliance substrate 260 includes a sealing layer 262 provided at the protective substrate 240 and a fixed plate 264 provided at the sealing layer 262. The sealing layer 262 is a layer for sealing the manifold 216. The sealing layer 262 has, for example, flexibility. The fixed plate 264 is provided with a through hole 266. The through hole 266 penetrates the fixed plate 264 in the Z-axis direction. The through hole 266 is provided at a position overlapping the manifold 216 when viewed from the Z-axis direction.

### Printer

Next, a printer according to the embodiment will be described with reference to the drawings. FIG. 13 is a perspective view schematically showing a printer 300 according to the embodiment.

The printer 300 is an inkjet printer. The printer 300 includes a head unit 310 as shown in FIG. 13. The head unit 310 includes, for example, the liquid ejection heads 200. The number of liquid ejection heads 200 is not particularly limited. The head unit 310 is detachably provided with cartridges 312 and 314 that constitute a supply unit. A carriage 316 on which the head unit 310 is mounted is axially movable on a carriage shaft 322 attached to a device main body 320, and ejects a liquid supplied from a liquid supply unit.

Here, the liquid may be a material in a state in which a substance is in a liquid phase, and a material in a liquid state such as a sol and a gel is also contained in the liquid. The liquid includes not only a liquid as one state of a substance, but also a composition that is obtained by dissolving, dispersing, or mixing particles of a functional material formed of a solid such as a pigment or a metal particle in a solvent. Typical examples of liquids include an ink and a liquid crystal emulsifier. The ink includes various liquid compositions such as a general water-based ink, an oil-based ink, a gel ink, and a hot-melt ink.

In the printer 300, a driving force of a driving motor 330 is transmitted to the carriage 316 via a plurality of gears (not shown) and a timing belt 332, whereby the carriage 316 on which the head unit 310 is mounted is moved along the carriage shaft 322. On the other hand, the device main body 320 is provided with a conveyance roller 340 as a conveyance mechanism that relatively moves a sheet S, which is a recording medium such as paper, with respect to the liquid ejection head 200. The conveyance mechanism that conveys the sheet S is not limited to the conveyance roller, and may be a belt, a drum, and the like.

The printer 300 includes a printer controller 350 as a control unit that controls the liquid ejection head 200 and the conveyance roller 340. The printer controller 350 is electrically coupled to the circuit substrate 250 of the liquid ejection head 200. The printer controller 350 includes, for example, a random access memory (RAM) that temporarily stores various data, a read only memory (ROM) that stores a control program and the like, a central processing unit (CPU), and a drive signal generation circuit that generates a drive signal to be supplied to the liquid ejection head 200.

Each of the piezoelectric elements 100, 100A, and 100B according to the embodiment is not limited to the liquid ejection head and the printer, and can be used in a wide range of applications. The piezoelectric elements 100, 100A, and 100B are suitably used as a piezoelectric actuator for, for example, an ultrasonic motor, a vibrating dust remover, a piezoelectric transformer, a piezoelectric speaker, a piezoelectric pump, and a pressure-electrical conversion device. The piezoelectric elements 100, 100A, and 100B are suitably used as a piezoelectric sensor element such as an ultrasonic detector, an angular velocity sensor, an acceleration sensor, a vibration sensor, an inclination sensor, a pressure sensor, a collision sensor, a motion sensor, an infrared sensor, a terahertz sensor, a heat detection sensor, a pyroelectric sensor, and a piezoelectric sensor. The piezoelectric elements 100, 100A, and 100B are suitably used as a ferroelectric element such as a ferroelectric memory (FeRAM), a ferroelectric transistor (FeFET), a ferroelectric arithmetic circuit (FeLogic), and a ferroelectric capacitor. The piezoelectric elements 100, 100A, and 100B are suitably used as a voltage-controlled optical element such as a wavelength converter, an optical waveguide, an optical path modulator, a refractive index control element, and an electronic shutter mechanism.

What is claimed is:

1. A method of manufacturing a piezoelectric element comprising:
a first film forming step of forming a first electrode at a substrate;
a second film forming step of forming a first piezoelectric layer at the first electrode;
a first processing step of patterning the first electrode and the first piezoelectric layer by etching; and
a third film forming step of forming, after the first processing step, a second piezoelectric layer to cover the first electrode, the first piezoelectric layer, and the substrate.

2. The method of manufacturing a piezoelectric element according to claim 1, further comprising:
a second processing step of patterning the second piezoelectric layer by etching; and
a fourth film forming step of forming a second electrode at the second piezoelectric layer after the second processing step.

3. The method of manufacturing a piezoelectric element according to claim 1, further comprising:
a fifth film forming step of forming the second electrode at the second piezoelectric layer; and
a third processing step of patterning the second piezoelectric layer and the second electrode by etching.

4. The method of manufacturing a piezoelectric element according to claim 3, further comprising:
a sixth film forming step of forming a conductive layer to cover the second electrode and the second piezoelectric layer.

5. The method of manufacturing a piezoelectric element according to claim 3, further comprising:
a seventh film forming step of forming a protective film at a side surface of the second piezoelectric layer.

6. The method of manufacturing a piezoelectric element according to claim 1, further comprising:
an eighth film forming step of forming an adhesion layer at the substrate; and
a fourth processing step of patterning the adhesion layer by etching, wherein
the eighth film forming step and the fourth processing step are performed before the first film forming step.
